(19) United States
(12) Patent Application Publication
(10) Pub. No.: US 2006/0023632 A1
(43) Pub. Date: Feb. 2, 2006

(54) System and method for detecting transient links in multi-hop wireless networks

(75) Inventors: Sebnem Z. Ozer, Altamonte Springs, FL (US); Surong Zeng, Altamonte Springs, FL (US)

Correspondence Address: GARDNER CARTON & DOUGLAS LLP;(MESHNETWORKS/MOTOROLA) ATTN: PATENT DOCKET DEPT., 191 NORTH WACKER DRIVE, SUITE 3700, CHICAGO, IL, 60606-1698, US

(73) Assignee: MeshNetworks, Inc., Maitland, FL (US)

(21) Appl. No.: 11/189,617

(22) Filed: Jul. 26, 2005

Related U.S. Application Data
(60) Provisional application No. 60/591,305, filed on Jul. 27, 2004.

(51) Int. Cl. G01R 31/08; H04B 7/005

(52) U.S. Cl. 370/248; 370/278

(57) ABSTRACT

The present invention provides a system and method to detect transient links in a timely and reliable way. The present invention introduces a metric that depends on the unicast data timeout measurements at the receiver node (102, 106, 107). This metric can be combined with existing solutions to estimate the link quality between nodes (102, 106, 107). Furthermore, the present invention takes the packet size into consideration when transceivers (108) update the link quality based on the packet completion rate to quantify the transient link quality more precisely.

This application claims the benefit of U.S. Provisional Application No. 60/591,305, filed Jul. 27, 2004, the entire content being incorporated herein by reference.

### FIELD OF THE INVENTION

The present invention relates to a system and method for detecting transient links between nodes in a wireless network. More particularly, the present invention relates to a system and method that considers packet size and packet failure rate to ascertain the quality of a link between nodes and to thus identify transient links more precisely based on their link quality.

### BACKGROUND

In recent years, a type of mobile communications network known as an “ad-hoc” network has been developed. As can be appreciated by one skilled in the art, network nodes transmit and receive data packet communications in a multiplexed format, such as time-division multiple access (TDMA) format, code-division multiple access (CDMA) format, or frequency-division multiple access (FDMA) format.

More sophisticated ad-hoc networks are also being developed which, in addition to enabling mobile nodes to communicate with each other as in a conventional ad-hoc network, further enable the mobile nodes to access a fixed network and thus communicate with other mobile nodes, such as those on the public switched telephone network (PSTN), and on other networks such as the Internet. Details of these advanced types of ad-hoc networks are described in U.S. patent application Ser. No. 09/897,790 entitled “Ad Hoc Peer-to-Peer Mobile Radio Access System Interfaced to the PSTN and Cellular Networks”, filed on Jun. 29, 2001, in U.S. patent application Ser. No. 09/815,157 entitled “Time Division Protocol for an Ad-Hoc, Peer-to-Peer Radio Network Having Coordinating Channel Access to Shared Parallel Data Channels with Separate Reservation Channel”, filed on Mar. 22, 2001, and in U.S. patent application Ser. No. 09/815,164 entitled “Prioritized-Routing for an Ad-Hoc, Peer-to-Peer, Mobile Radio Access System”, filed on Mar. 22, 2001, the entire content of each being incorporated herein by reference.

Due to the differences in radio transceiver capabilities and perceived interference levels of nodes, unidirectional links are common in mobile ad-hoc networks. In addition, there are links called “transient links” (Chin K-W., Judge J., Williams A. and Kermode R., “Implementation Experience with MANET Routing Protocols,” ACM Sigcomm Computer Communications Review, Vol. 32, No 5, November 2002) or “communication gray zones” (Lundgren H., Nordstrom E., Tschudin C., “Coping with Communication Gray Zones in IEEE 802.11b based Ad hoc Networks”, WoWMoM 2002), both of these documents being incorporated by reference herein). In such zones, the data loss is severe but still small messages (e.g. control and reservation messages including request-to-send (RTS), clear-to-send (CTS) and Hello messages) can be exchanged successfully. The main reason is that data and control messages are in general transmitted at different rates, size and modulation. Furthermore, in multi-channel networks they are sent at different frequency ranges. In addition, broadcast messages are not acknowledged and the sender can not measure the success rate. As the mobility increases, the number of fluctuating links at the transmission borderlines increases. The impact of these links may be severe on routing protocols that use control messages or a small number of data messages with small packet size. There are different solutions that have been developed in an attempt to overcome these problems depending on the routing scheme.

For example, learning about the unidirectional links can introduce higher delay and overhead (Marina M. K. and Das S. R., “Routing Performance in the Presence of Unidirectional Links in Multihop Wireless Networks,” Mobihoc 2002, incorporated by reference herein). One of the solutions for Ad Hoc On-Demand Distance Vector (AODV) type routing protocols is blacklisting (Charles E. Perkins, Elizabeth M. Belding-Royer, Samir R. Das, “Ad hoc On-Demand Distance Vector (AODV) Routing”, ietf draft January 2002, incorporated by reference herein). That is, whenever, a node detects a Route Reply (RREP) transmission failure, it inserts the next hop of the failed RREP into a blacklist set. When there are a lot of unidirectional links, this approach becomes inefficient (Marina M. K. and Das S. R., “Routing Performance in the Presence of Unidirectional Links in Multihop Wireless Networks,” Mobihoc 2002, incorporated by reference herein). Furthermore, the technique depends on the specific timeout value that specifies the period for which a node remains in the blacklist.

Another method is to use periodic one-hop Hello messages where all nodes from which the sender can hear Hellos are included. If a node hears a Hello message where its node id is not included, it marks the corresponding link as unidirectional. A documented entitled “Coping with Communication Gray Zones in IEEE 802.11b based Ad hoc Networks” by Lundgren H., Nordstrom E., and Tschudin C., WoWMoM 2002, incorporated by reference herein, proposes to send n consecutive hellos. However, large and frequent Hello packets increase the overhead significantly. Another solution proposed in “Routing Performance in the Presence of Unidirectional Links in Multihop Wireless Networks,” by Marina M. K. and Das S. R., Mobihoc 2002, incorporated by reference herein, uses a distributed search procedure where multiple RREPs explore bidirectional paths. When RREP fails at a node, the corresponding reverse path is erased and the RREP is retried along an alternate reverse path if available. In general, Route Request (RREQ) (mostly broadcasted) and RREP type of messages are smaller than MTU size to decrease the overhead. There are also alternative approaches. In a document entitled “Providing a Bidirectional Abstraction for Unidirectional Ad Hoc Networks,” by Ramasubramanian V., Chandra R. and Mosse D., IEEE Infocom 2002, and “A Tunneling Approach to Routing with Unidirectional Links in Mobile Ad-Hoc Networks,” by Nesargi S. and Prakash R., IC3N 2000, both incorporated by reference herein, sub-routing layer and link-layer tunneling are proposed to use unidirectional links in the routing protocols. However, these solutions do not solve the transient link problems where control messages can be exchanged with much higher probability than the data messages as explained above. Furthermore, once the route is established they do not detect link quality degradation until the route is broken.

Accordingly, a need exists for a system and method for detecting transient links in a wireless network, in particular, a wireless multi-hop network, in a timely and accurate manner to provide symmetric link quality estimations to enable the selection of optimal links.

### BRIEF DESCRIPTION OF THE FIGURES

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 is a block diagram of an example ad-hoc wireless communications network including a plurality of nodes employing a system and method in accordance with an embodiment of the present invention;

FIG. 2 is a block diagram illustrating an example of a mobile node employed in the network shown in FIG. 1; and

FIG. 3 is a block diagram illustrating an example of a network according to an embodiment of the present invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Before describing in detail embodiments that are in accordance with the present invention, it should be observed that the embodiments reside primarily in combinations of method steps and apparatus components related to detecting transient links in a wireless multi-hop network. Accordingly, the apparatus components and method steps have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

It will be appreciated that embodiments of the invention described herein may be comprised of one or more conventional processors and unique stored program instructions that control the one or more processors to implement, in conjunction with certain non-processor circuits, some, most, or all of the functions of a system and method for detecting transient links in a multi-hop network described herein. The non-processor circuits may include, but are not limited to, a radio receiver, a radio transmitter, signal drivers, clock circuits, power source circuits, and user input devices. As such, these functions may be interpreted as steps of a method to perform the detection of transient links in a multi-hop network. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used. Thus, methods and means for these functions have been described herein. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

As will now be described in detail, the present invention provides a system and method to detect transient links in a timely and reliable way. Specifically, the present invention introduces a metric that depends on the unicast data timeout measurements at the receiver side. This metric can be combined with existing solutions to estimate the link quality between nodes. Furthermore, the present invention takes the packet size into consideration when transceivers update the link quality based on the packet completion rate to quantify the transient link quality more precisely.

As will be appreciated from the following, the system and method according to embodiments of the present invention described herein are capable of detecting transient links in a timely and accurate way to provide symmetric link quality estimations. The techniques are complimentary to the solutions that use link quality estimation for optimal neighbor and route selection described in a U.S. patent application by Avinash Joshi entitled “System and Method For Achieving Continuous Connectivity to an Access Point or Gateway in a Wireless Network Following an On-demand Routing Protocol and to Perform Smooth Handoff of Mobile Terminals between Fixed Terminals in the Network,” Ser. No. 10/755,346 filed Jan. 13, 2004, published U.S. Patent Application No. 2004/0143842, herein incorporated by reference in its entirety. The embodiments of the present invention use control and data packets' signal strength when available along with layer 2 (L2) feedbacks at the transmitter site (e.g. packet loss estimated from the acknowledgment packets). An example of a technique for rejecting control packets lower than a desired signal quality is described in a publication entitled “Coping with Communication Gray Zones in IEEE 802.11b based Ad hoc Networks,” by Lundgren H., Nordstrom E., and Tschudin C., WoWMoM 2002, incorporated herein by reference. However, that technique can result in connectivity problems because that technique can reject the only available route.

Another technique, known as a Multiple Access Collision Avoidance (MACA) technique is described by Karn, P., in a publication entitled “MACA—a new channel access method for packet radio,” ARRL/CRRL Amateur Radio 9th Computer Networking Conference, pp. 134-40, ARRL 1990, which is incorporated herein by reference. The technique described in that publication is a common technique used for mobile multi-hop networks. The technique uses reservation messages to avoid packet collisions by using request-to-send (RTS) and clear-to-send (CTS) messages. The transmission between sender and receiver consists of RTS-CTS-DATA messages. Another technique known as Multiple Access Collision Avoidance for Wireless (MACAW) is described by Bharghavan, V.; Demers, A.; Shenker, S.; Zhang, L., in a publication entitled “MACAW: A media access protocol for wireless LAN's,” Computer Communication Review, vol. 24, (no.4), (ACM SIGCOMM '94 Conference on Communications Architectures, Protocols and Applications, London, UK, 31 August-2 September 1994.) October 1994. p. 212-25, incorporated herein by reference. The MACAW technique extends MACA by introducing data-sending (DS) and acknowledgment (ACK) messages to form RTS-CTS-DS-DATA-ACK message exchange and a new backoff algorithm. The IEEE 802.11 MAC is a variation of CSMA/CA protocol that implements both carrier sensing and virtual (RTS-CTS exchange) carrier sensing with acknowledgment messages to improve reliability. The techniques according to the embodiments of the present invention described herein are applicable to all these MAC schemes, e.g. MACA, MACAW and 802.11 MAC protocols and their variants.

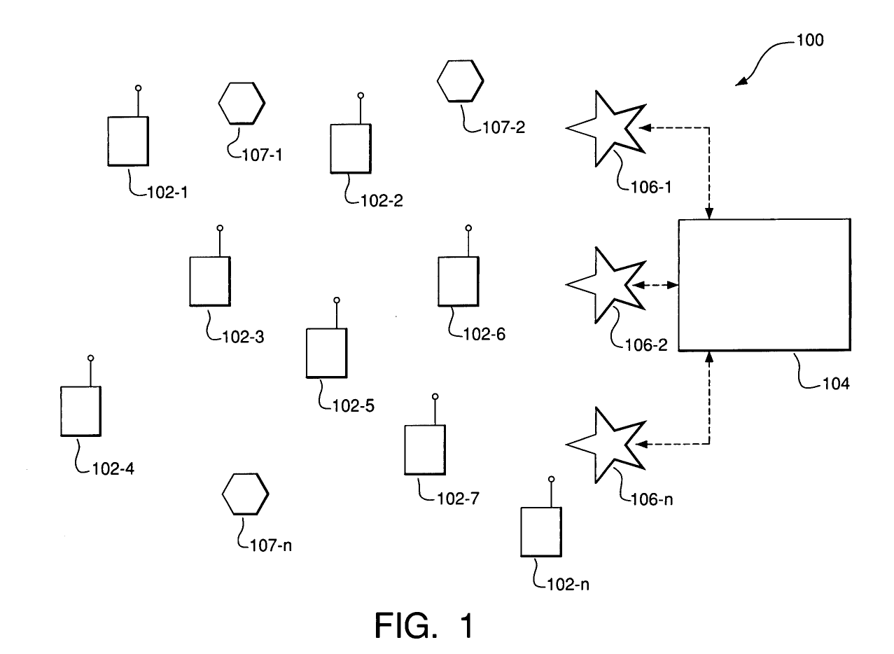

Turning now to the figures, FIG. 1 is a block diagram illustrating an example of an ad-hoc packet-switched wireless communications network 100 employing an embodiment of the present invention. Specifically, the network 100 includes a plurality of mobile wireless user terminals 102-1 through 102-n (referred to generally as nodes 102 or mobile nodes 102), and can, but is not required to, include a fixed network 104 having a plurality of access points 106-1, 106-2, 106-n (referred to generally as nodes 106 or access points 106), for providing nodes 102 with access to the fixed network 104. The fixed network 104 can include, for example, a core local access network (LAN), and a plurality of servers and gateway routers to provide network nodes with access to other networks, such as other ad-hoc networks, the public switched telephone network (PSTN) and the Internet. The network 100 further can include a plurality of fixed routers 107-1 through 107-n (referred to generally as nodes 107 or fixed routers 107) for routing data packets between other nodes 102, 106 or 107. It is noted that for purposes of this discussion, the nodes discussed above can be collectively referred to as “nodes 102, 106 and 107”, or simply “nodes”.

As can be appreciated by one skilled in the art, the nodes 102, 106 and 107 are capable of communicating with each other directly, or via one or more other nodes 102, 106 or 107 operating as a router or routers for packets being sent between nodes, as described in U.S. patent application Ser. Nos. 09/897,790, 09/815,157 and 09/815,164, referenced above.

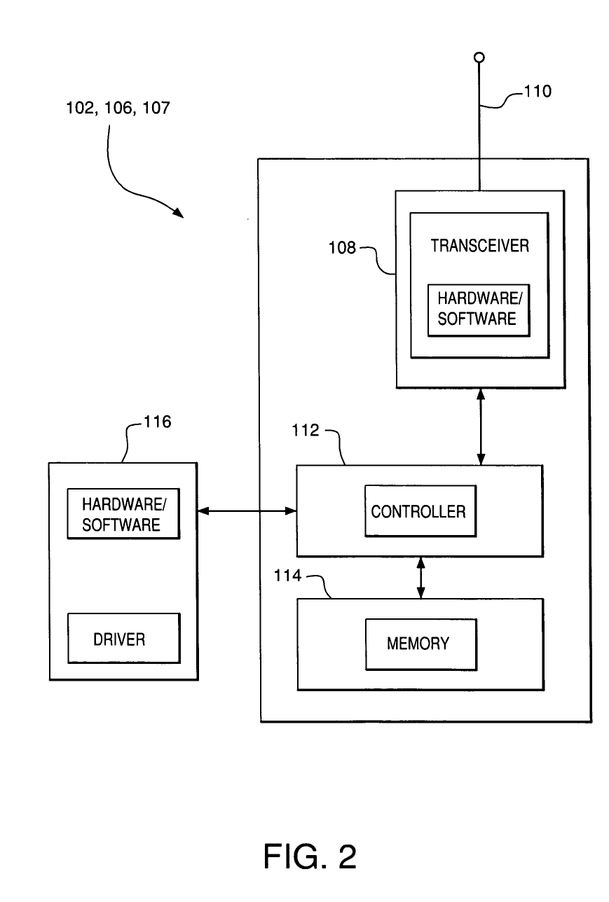

As shown in FIG. 2, each node 102, 106 and 107 includes a transceiver, or modem 108, which is coupled to an antenna 110 and is capable of receiving and transmitting signals, such as packetized signals, to and from the node 102, 106 or 107, under the control of a controller 112. The packetized data signals can include, for example, voice, data or multimedia information, and packetized control signals, including node update information.

Each node 102, 106 and 107 further includes a memory 114, such as a random access memory (RAM) that is capable of storing, among other things, routing information pertaining to itself and other nodes in the network 100. As further shown in FIG. 2, certain nodes, especially mobile nodes 102, can include a host 116 which may consist of any number of devices, such as a notebook computer terminal, mobile telephone unit, mobile data unit, or any other suitable device. Each node 102, 106 and 107 also includes the appropriate hardware and software to perform Internet Protocol (IP) and Address Resolution Protocol (ARP), the purposes of which can be readily appreciated by one skilled in the art. The appropriate hardware and software to perform transmission control protocol (TCP) and user datagram protocol (UDP) may also be included.

The approach described herein uses L2 feedback (such as data timeouts after sending a CTS) at the receiver to compute an average link quality metric in order to detect transient links without introducing overhead and delay.

A MACA type system will be used to describe an embodiment of the present invention. The sender sends a request-to-send (RTS) message to reserve the transmission medium. The receiver replies with a clear-to-send (CTS) message. RTS and CTS messages are transmitted over a reservation channel (or any other suitable channel, such as a data channel) while data and acknowledgment (ACK) messages may be transmitted via the same channel or a different data channel. Every node that hears RTS and/or CTS sets the corresponding addresses and channels as busy for the amount of time required for the transmission. The routing protocol can be a reactive, proactive or hybrid type where several small size broadcast and unicast system messages are used to establish the routes. The protocol should not transmit frequent and large system packets to establish the routes, which is important for an efficient routing scheme. However, these types of routing protocols are affected significantly by transient links where data loss is severe but small messages (e.g. control and reservation messages including request-to-send (RTS), clear-to-send (CTS) and Hello messages) can still be exchanged successfully.

The system and method of the present invention counts the data timeouts after the CTS is sent. In transient links, RTS and CTS completion rate may be high but data completion rate may be very low. Therefore, after the route is established, the receiver will experience a large amount of data timeouts. With the integration of this metric into other signal quality measurements, the receiver can detect that the link is a transient link. Note that without this metric, the receiver would perceive the link as a good link since small control and system message completion rate is not low. Unless the transmitter carries its perceived link quality as described in “System and Method for Characterizing the Quality of a Link in a Wireless Network” by Avinash Josh and Guenael Strutt filed Jun. 7, 2004, application Ser. No. 10/863,534, herein incorporated by reference in its entirety, the receiver will not be able to estimate unicast data completion rate from the transmitter site. However, carrying this information may increase overhead. Furthermore, depending on the message type where this information is carried, the probability that this packet will be successfully received may be low.

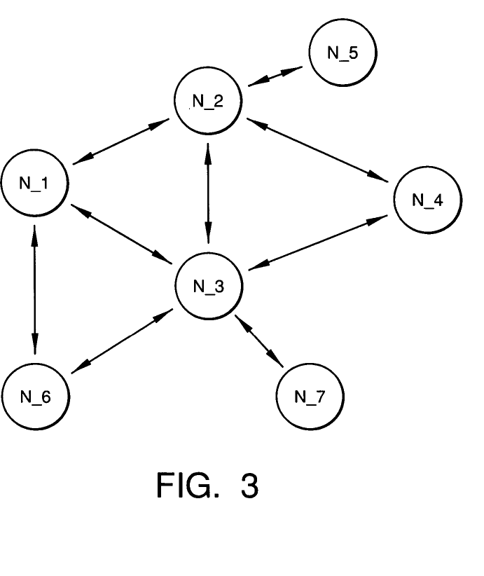

In FIG. 3, an example scenario is illustrated to demonstrate the benefits of the present invention. N_1 through N_7 represent nodes described above with regard to FIGS. 1 and 2. In this example, the link between N_1 and N_2 has transient link characteristics. N_2 and N_1 can receive control messages and hello messages with high success probability while unicast data transmission has severe packet loss. For example, if N_1 is the source and N_4 is the destination for a traffic session, both N_2 and N_3 are good candidates to serve as intermediate relaying nodes. After establishing the route to N_2, N_1 can use the L2 feedbacks (such as No ACK) to decrease the link quality metric and after some packet loss can choose another route that passes from N_3.

An existing solution to the situation described above is to send the link quality metric estimated at N_1 to N_2. However, since most of the unicast data transmissions are not successful between N_1 and N_2, the probability that N_2 will have the updated link quality metrics is low if this metric is sent via data messages. If this information is sent via control messages, it will not be compatible with standards such as 802.11 and increase the overhead. If N_{—}2 timely changed its estimated link quality metric for N_1, it would be faster to change the route.

Another problem arises when N_5 tries to set up a route to N_6 as N_2 can choose N_1 as a next hop because N_2 still has a good view for the link between itself and N_1 (due to the successful control messages). Again, if N_2 changed its estimated link quality metric for N_1 when N_1 started to send data to N_2, it would be faster to establish the optimal route. The present invention allows the nodes to overcome transient link problems by providing a faster and more reliable way to have symmetric link quality estimations. It can be combined with other existing solutions as a complimentary technique.

The statistics of this metric depend on the dynamic behavior of the nodes, channel and traffic characteristics. Therefore, an important feature is to have a metric that reflects the time span of the transient link. Therefore, for each link the last updated time may be kept to use in a moving average as suggested in “A system and traffic dependent adaptive routing algorithm for ad hoc networks,” by P. Gupta and P. Kumar, IEEE Conference on Decision and Control 1997, incorporated herein by reference.

A further point regarding existing link quality estimation can be found from the description above. The small packets generally have a higher completion rate than the large packets. However, the transceiver updates the link quality based on the packet completion rate without differentiating the various packet sizes. The technique according to the present invention therefore extends the current link quality estimation proposed in published U.S. Patent Application 2003/0189906, “System and method for providing adaptive control of transmit power and data rate in an ad-hoc communication network,” incorporated by reference herein, by taking packet size into the consideration. When the transmitter node detects a success of a small packet transmission, the transmitter node should increase the link quality by a small step. A small packet can be a control message, a reservation message or short routing packets such as RREQ, RREP, and so on. For purposes of example, a small packet can be any message shorter than 100 bytes, and a large packet can be any message 100 bytes or greater. However, the size of a small packet is not limited to only less than 100 bytes, but rather, can be any suitable size relative to what would be viewed as a large packet as can be appreciated by one skilled in the art. A small step can be viewed as any magnitude less than what would be viewed as a large step as can be appreciated by one skilled in the art. When the transmitter detects the success of a large transmission, it should increase the link quality by a large step, which can be any suitable value have a magnitude greater than what would be viewed as a small step as can be appreciated by one skilled in the art. This update is done both at the transmitter and the receiver of the respective nodes.

Similarly, when a failure of a transmission is detected, the transmitter node should degrade the link quality more aggressive when the packet size is small. On the receiver side, because the RTS carries the packet size, the receiver node also can obtain the packet size information. If the data packet timeout occurs for a small packet, the receiver node also should penalize the link quality more aggressively. However, if the data packet timeout occurs for a large packet, the receiver node reduces the link quality by a small step, which can be any suitable value smaller than what would be viewed as a large step as can be appreciated by one skilled in the art. It is also noted that the values of the step sizes by which the link quality is adjusted for packet success and failure can be proportionate to the packet size. For example, if a small packet (e.g., less than 100 bytes) fails, the link quality can be degraded by X %. If a larger packet (e.g., 500 bytes) fails, the link quality can be degraded by Y %, and if an even larger packet fails (e.g., 1000 bytes), the link quality can be degraded by Z%, where X>Y>Z. That is, the link quality is degraded by a larger amount for a smaller packet size that failed. Likewise, if a small packet (e.g., less than 100 bytes) is successfully received, the link quality can be upgraded by A%. If a larger packet (e.g., 500 bytes) succeeds, the link quality can be upgraded by B %, and if an even larger packet succeeds (e.g., 1000 bytes), the link quality can be upgraded by C %, where C>B>A. That is, the link quality is upgraded by a larger amount for a larger packet size received. The packet size factor can thus reflect how serious the transient link is, that is, the level of unreliability of the link, and make the link quality estimation converge faster. Thus, the present invention uses packet size as a feedback along with the packet completion rate for the link quality estimation in order to estimate the actual link quality faster. It should be understood by one skilled in the art that the above operations, such as the detection of success or failure of data packet transmission, the updating of the link quality, and the determination as to whether a link is a transient link, can be performed by the controller 112 of a transmitting or receiving node, or both, or by any other suitable components. The controller 112 present at the transmitting node, receiving node, or both, or such other suitable components, can be referred to collectively in general as a “controller” for performing these operations, and in the event the term “controller” is used to refer collectively to controllers 112 or other suitable components at the transmitting and receiving nodes, the respective controllers 112 or other components at the respective transmitting and receiving nodes can be referred to as the transmitting node controller and receiving node controller.

The receiver based link quality metric estimation increases the performance of adaptive transport protocols. For instance, the receiver that has a timely estimation of reception success rates for different packet sizes can inform the transmitters to adjust their rates, fragmentation and power levels accordingly.

In the foregoing specification, specific embodiments of the present invention have been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

We claim:

1. A method for detecting a transient link in a wireless network, the method comprising:
transmitting data between a transmitting node and a receiving node;
counting data timeouts that occur at the receiving node; and
determining whether a link between the transmitting and receiving nodes is a transient link based on a counted number of data timeouts.

2. A method as claimed in claim 1, wherein:
the counting step comprises controlling at least one of the transmitting node and the receiving node to count the data timeouts.

3. A method as claimed in claim 2, wherein:
the controlling step comprises controlling the transmitting and receiving nodes to count the data timeouts.

4. A method as claimed in claim 1, further comprising:
assessing the quality of the link based on the counted number of data timeouts; and
the determining step identifies the link as a transient link when the quality of the link is below a desired criteria.

5. A method as claimed in claim 4, wherein:
the determining step determines a level of unreliability of the transient link based on a value of the quality of the link.

6. A method as claimed in claim 4, wherein:
the assessing step adjusts a quality value representing the quality of the link based on the counted number of data timeouts and the respective sizes of the data packets for which timeout occurred.

7. A method as claimed in claim 6, wherein:
the assessing step adjusts the quality value by a large amount when timeout occurs for a small data packet and by a small amount when timeout occurs for large data packet.

8. A method as claimed in claim 4, wherein:
the adjusting step comprises determining the respective size of a respective data packet based on information included in a request-to-send (RTS) message sent by the transmitting node.

9. A system for detecting a transient link in a wireless network, the system comprising:
a transmitting node and a receiving node, the transmitting node being adapted to transmit data to the receiving node;
a controller, adapted to count data timeouts that occur at the receiving node, and adapted to determine whether a link between the transmitting and receiving nodes is a transient link based on a counted number of data timeouts.

10. A system as claimed in claim 9, wherein:
the controller comprises at least one of the following to count the data timeouts:
a transmitting node controller disposed at the transmitting node; and
a receiving node controller disposed at the receiving node.

11. A system as claimed in claim 10, wherein:
the controller comprises transmitting and receiving node controllers disposed respectively at the transmitting and receiving nodes to count the data timeouts.

12. A system as claimed in claim 9, wherein:
the controller is further adapted to assess the quality of the link based on the counted number of data timeouts, and to identify the link as a transient link when the quality of the link is below a desired criteria.

13. A system as claimed in claim 12, wherein:
the controller is adapted to determine a level of unreliability of the transient link based on a value of the quality of the link.

14. A system as claimed in claim 12, wherein:
the controller is further adapted to adjust a quality value representing the quality of the link based on the counted number of data timeouts and the respective sizes of the data packets for which timeout occurred.

15. A system as claimed in claim 14, wherein:
the controller is adapted to adjust the quality value by a large amount when timeout occurs for a small data packet and by a small amount when timeout occurs for large data packet.

16. A system as claimed in claim 12, wherein:
the controller is adapted to determine the respective size of a respective data packet based on information included in a request-to-send (RTS) message sent by the transmitting node.

17. A node, adapted for use in a wireless network, the node comprising:
a transceiver, adapted to transmit data to another node in the wireless network; and
a controller, adapted to count data timeouts that occur at the another node, and adapted to determine whether a link between the node and the another node is a transient link based on a counted number of data timeouts.

18. A node as claimed in claim 17, wherein:
the controller is further adapted to assess the quality of the link based on the counted number of data timeouts, and to identify the link as a transient link when the quality of the link is below a desired criteria.

19. A node as claimed in claim 17, wherein:
the controller is further adapted to adjust a quality value representing the quality of the link based on the counted number of data timeouts and the respective sizes of the data packets for which timeout occurred.

20. A node as claimed in claim 19, wherein:
the controller is adapted to adjust the quality value by a large amount when timeout occurs for a small data packet and by a small amount when timeout occurs for large data packet.
